(19) United States
(12) Patent Application Publication
(10) Pub. No.: US 2026/0026065 A1
(43) Pub. Date: Jan. 22, 2026

(54) SEMICONDUCTOR DEVICE STRUCTURES AND METHODS OF FORMING THE SAME

(71) Applicant: TAIWAN SEMICONDUCTOR MANUFACTURING COMPANY, LTD., Hsinchu (TW)

(72) Inventors: Wei Shun HUANG, Tainan (TW); Yuan Tsung TSAI, Tainan (TW); Ying Ming WANG, Tainan (TW); I-I CHENG, Tainan (TW); Li-Yi CHEN, Tainan (TW)

(21) Appl. No.: 18/925,169

(22) Filed: Oct. 24, 2024

Related U.S. Application Data
(60) Provisional application No. 63/673,682, filed on Jul. 20, 2024.

(51) Int. Cl. H01L 29/66; H01L 29/78

(52) U.S. Cl. CPC H10D 64/017; H10D 30/024; H10D 30/6217

(57) ABSTRACT

A semiconductor device structure, along with methods of forming such, are described. The semiconductor device structure includes an active region, and the active region includes a fin extending over a substrate, a first dummy gate electrode layer disposed over the fin, a second dummy gate electrode layer adjacent the first dummy gate electrode layer, a third dummy gate electrode layer disposed over the fin and a fourth dummy gate electrode layer adjacent the third dummy gate electrode layer. The second and third dummy gate electrode layers are disposed between the first and fourth dummy gate electrode layers. The active region further includes an active gate electrode layer disposed over the fin, and the active gate electrode layer is disposed between the second and third dummy gate electrode layers.

### CROSS-REFERENCE TO RELATED APPLICATIONS

This application claims priority to U.S. Provisional Application Ser. No. 63/673,682 filed Jul. 20, 2024, which is incorporated by reference in its entirety.

### BACKGROUND

The semiconductor integrated circuit (IC) industry has experienced exponential growth. Technological advances in IC materials and design have produced generation of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs.

Accompanying the scaling down of devices, manufacturers have begun using new and different materials and/or combination of materials to facilitate the scaling down of devices. Scaling down, alone and in combination with new and different materials, has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, and 3 are perspective views of a semiconductor device structure, in accordance with some embodiments.

FIG. 4 is a cross-sectional side view of the semiconductor device structure, in accordance with some embodiments.

FIG. 5 is a perspective view of the semiconductor device structure, in accordance with some embodiments.

FIG. 6 is a cross-sectional side view of the semiconductor device structure, in accordance with some embodiments.

FIGS. 7A, 8A, 9A, and 10A are cross-sectional side views of various stages of manufacturing the semiconductor device structure of FIG. 5 taken along line A-A, in accordance with some embodiments.

FIGS. 7B, 8B, 9B, and 10B are cross-sectional side views of various stages of manufacturing the semiconductor device structure of FIG. 5 taken along line B-B, in accordance with some embodiments.

FIGS. 7C, 8C, 9C, and 10C are cross-sectional side views of various stages of manufacturing the semiconductor device structure of FIG. 5 taken along line C-C, in accordance with some embodiments.

FIG. 11 is a cross-sectional side view of the semiconductor device structure, in accordance with some embodiments.

FIGS. 12A, 12B, and 12C are cross-sectional side views of various stages of manufacturing the semiconductor device structure of FIG. 5 taken along lines A-A, B-B, and C-C, respectively, in accordance with some embodiments.

FIG. 13 is a cross-sectional side view of the semiconductor device structure, in accordance with some embodiments.

FIGS. 14A, 14B, and 14C are cross-sectional side views of various stages of manufacturing the semiconductor device structure of FIG. 5 taken along lines A-A, B-B, and C-C, respectively, in accordance with some embodiments.

FIG. 15 is a cross-sectional side view of the semiconductor device structure, in accordance with some embodiments.

FIGS. 16A and 16B are cross-sectional side views of various stages of manufacturing the semiconductor device structure of FIG. 5 taken along lines A-A and B-B, respectively, in accordance with some embodiments.

FIG. 17 is a cross-sectional side view of the semiconductor device structure, in accordance with some embodiments.

FIGS. 18A and 18B are cross-sectional side views of various stages of manufacturing the semiconductor device structure of FIG. 5 taken along lines A-A and B-B, respectively, in accordance with some embodiments.

FIG. 19 is a cross-sectional side view of the semiconductor device structure, in accordance with some embodiments.

FIGS. 20, 21, and 22 are top views of the semiconductor device structure, in accordance with some embodiments.

FIGS. 23A, 23B, 23C, and 23D are top views of the semiconductor device structure, in accordance with some embodiments.

FIG. 24 is a top view of the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

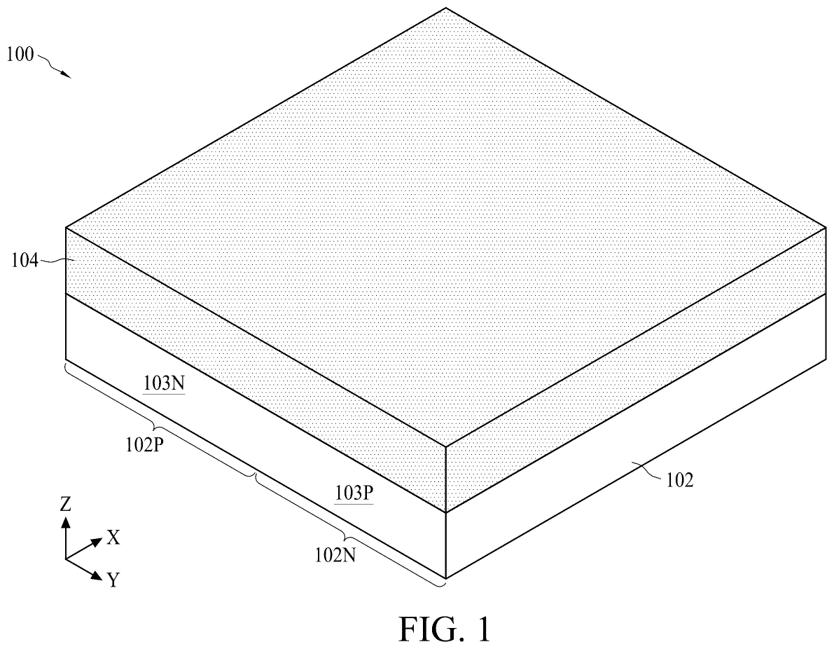

FIGS. 1-24 illustrate various stages of manufacturing a semiconductor device structure 100 in accordance with various embodiments of this disclosure. It is understood that additional operations can be provided before, during, and after processes shown by FIGS. 1-24 and some of the operations described below can be replaced or eliminated, for additional embodiments of the method. The order of the operations/processes may be interchangeable.

FIGS. 1, 2, and 3 are perspective views of a semiconductor device structure 100, in accordance with some embodiments. In FIG. 1, a first semiconductor layer 104 is formed on a substrate 102. The substrate may be a part of a chip in a wafer. In some embodiments, the substrate 102 is a bulk semiconductor substrate, such as a semiconductor wafer. For example, the substrate 102 is a silicon wafer. The substrate 102 may include silicon or another elementary semiconductor material such as germanium. In some other embodiments, the substrate 102 includes a compound semiconductor. The compound semiconductor may include gallium arsenide, silicon carbide, indium arsenide, indium phosphide, another suitable semiconductor material, or a combination thereof. In some embodiments, the substrate 102 is a semiconductor-on-insulator (SOI) substrate. The SOI substrate may be fabricated using a separation by implantation of oxygen (SIMOX) process, a wafer bonding process, another applicable method, or a combination thereof.

The substrate 102 may be doped with P-type or N-type impurities. As shown in FIG. 1, the substrate 102 has a P-type metal-oxide-semiconductor region 102P (PMOS region 102P) and an N-type metal-oxide-semiconductor region 102N (NMOS region 102N) adjacent to the PMOS region 102P, in accordance with some embodiments. While not shown in scale in some figures, the PMOS region 102P and NMOS region 102N belong to a continuous substrate 102. In some embodiments of the present disclosure, the PMOS region 102P is used to form a PMOS structure thereon, whereas the NMOS region 102N is used to form an NMOS structure thereon. In some embodiments, an N-well region 103N and a P-well region 103P are formed in the substrate 102, as shown in FIG. 1. For example, the N-well region 103N is formed in the substrate 102 in the PMOS region 102P, whereas the P-well region 103P is formed in the substrate 102 in the NMOS region 102N. The P-well region 103P and the N-well region 103N may be formed by any suitable technique, for example, by separate ion implantation processes in some embodiments. By using two different implantation mask layers (not shown), the P-well region 103P and the N-well region 103N can be sequentially formed in different ion implantation processes.

The first semiconductor layer 104 is deposited over the substrate 102, as shown in FIG. 1. The first semiconductor layer 104 may be made of any suitable semiconductor material, such as silicon, germanium, III-V semiconductor material, or combinations thereof. In some embodiments, the first semiconductor layer 104 is substantially made of silicon. The first semiconductor layer 104 may be formed by an epitaxial growth process, such as metal-organic chemical vapor deposition (MOCVD), metal-organic vapor phase epitaxy (MOVPE), plasma-enhanced chemical vapor deposition (PECVD), remote plasma chemical vapor deposition (RP-CVD), molecular beam epitaxy (MBE), hydride vapor phase epitaxy (HVPE), liquid phase epitaxy (LPE), chloride vapor phase epitaxy (CI-VPE), or any other suitable process.

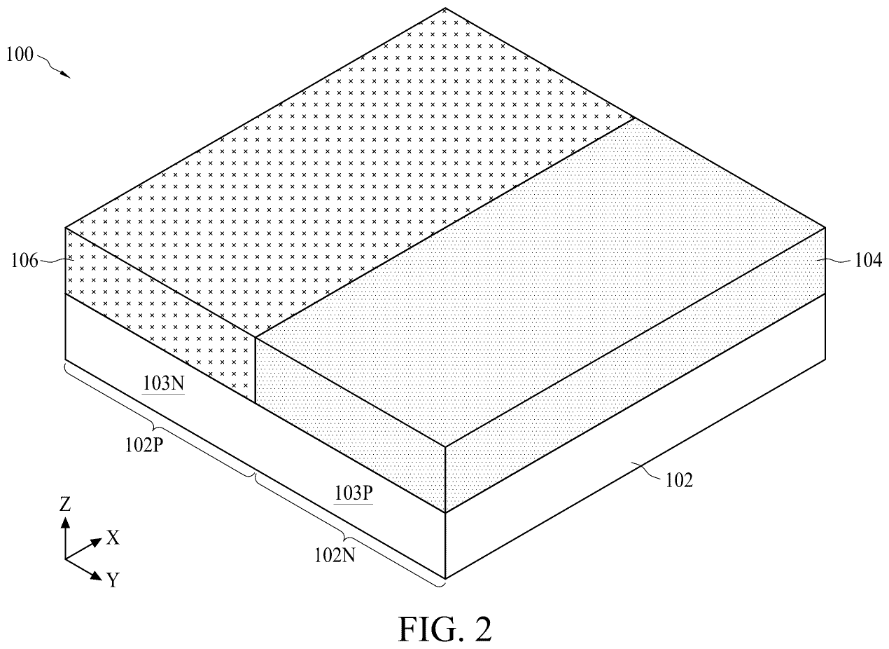

In FIG. 2, the portion of the first semiconductor layer 104 disposed over the N-well region 103N is removed, and a second semiconductor layer 106 is formed over the N-well region 103N and adjacent the portion of the first semiconductor layer 104 disposed over the P-well region 103P. A patterned mask layer (not shown) may be first formed on the portion of the first semiconductor layer 104 disposed over the P-well region 103P, and the portion of the first semiconductor layer 104 disposed over the N-well region 103N may be exposed. A removal process, such as a dry etch, wet etch, or a combination thereof, may be performed to remove the portion of the first semiconductor layer 104 disposed over the N-well region 103N, and the N-well region 103N may be exposed. The removal process does not substantially affect the mask layer (not shown) formed on the portion of the first semiconductor layer 104 disposed over the P-well region 103P, which protects the portion of the first semiconductor layer 104 disposed over the P-well region 103P. Next, the second semiconductor layer 106 is formed on the exposed N-well region 103N. The second semiconductor layer 106 may be made of any suitable semiconductor material, such as silicon, germanium, III-V semiconductor material, or combinations thereof. In some embodiments, the second semiconductor layer 106 is substantially made of silicon germanium. The second semiconductor layer 106 may be formed by the same process as the first semiconductor layer 104. For example, the second semiconductor layer 106 may be formed on the exposed N-well region 103N by an epitaxial growth process, which does not form the second semiconductor layer 106 on the mask layer (not shown) disposed on the first semiconductor layer 104. As a result, the first semiconductor layer 104 is disposed over the P-well region 103P in the NMOS region 102N, and the second semiconductor layer 106 is disposed over the N-well region 103N in the PMOS region 102P.

Portions of the first semiconductor layer 104 may serve as channels in the subsequently formed NMOS structure in the NMOS region 102N. Portions of the second semiconductor layer 106 may serve as channels in the subsequently formed PMOS structure in the PMOS region 102P. In some embodiments, the NMOS structure and the PMOS structure are FinFETs. While embodiments described in this disclosure are described in the context of FinFETs, implementations of some aspects of the present disclosure may be used in other processes and/or in other devices, such as planar FETs, nanostructure channel FETs, Horizontal Gate All Around (HGAA) FETs, Vertical Gate All Around (VGAA) FETs, and other suitable devices.

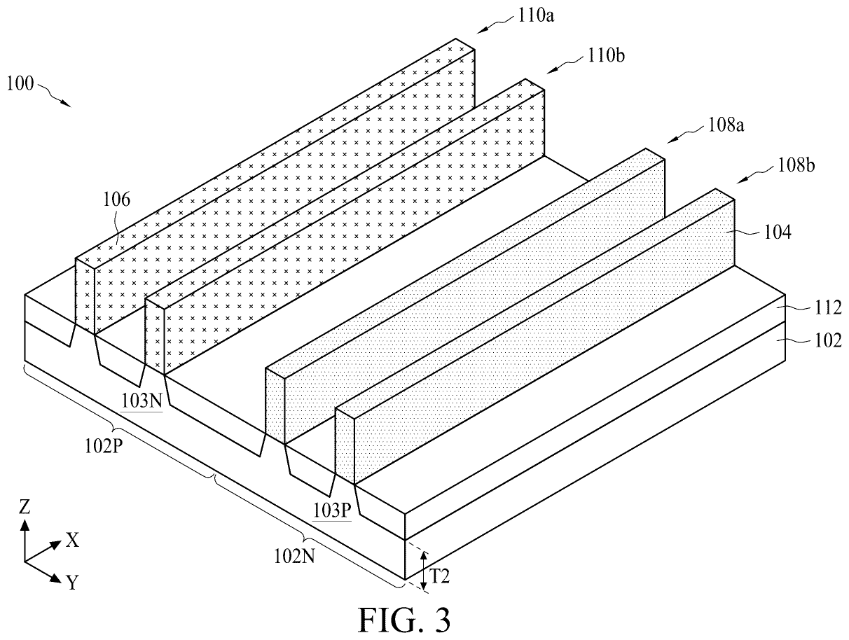

In FIG. 3, a plurality of fins 108a, 108b, 110a, 110b are formed from the first and second semiconductor layers 104, 106. The fins 108a, 108b, 110a, 110b may be patterned by any suitable method. For example, the fins 108a, 108b, 110a, 110b may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer (not shown) is formed over a substrate and patterned using a photolithography process. Spacers (not shown) are formed alongside the patterned sacrificial layer using a self-aligned process. The sacrificial layer is then removed, and the remaining spacers may then be used to pattern the substrate and form the fins.

The fins 108a, 108b may each include the first semiconductor layer 104, and a portion of the first semiconductor layer 104 may serve as an NMOS channel. Each fin 108a, 108b may also include the P-well region 103P. Likewise, the fins 110a, 110b may each include the second semiconductor layer 106, and a portion of the second semiconductor layer 106 may serve as a PMOS channel. Each fin 110a, 110b may also include the N-well region 103N. A mask (not shown) may be formed on the first and second semiconductor layers 104, 106, and may remain on the fins 108a-b and 110a-b.

Next, an insulating structure 112 is formed between adjacent fins 108a-b, 110a-b. The insulating structure 112 may be first formed between adjacent fins 108a-b, 110a-b and over the fins 108a-b, 110a-b, so the fins 108a-b, 110a-b are embedded in the insulating structure 112. The insulating structure 112 may include an oxygen-containing material, such as silicon oxide, carbon or nitrogen doped oxide, or fluorine-doped silicate glass (FSG); a nitrogen-containing material, such as silicon nitride, silicon oxynitride (SiON), SiOCN, SiCN; a low-K dielectric material (e.g., a material having a K value lower than that of silicon dioxide); or any suitable dielectric material. The insulating structure 112 may be formed by any suitable method, such as low-pressure chemical vapor deposition (LPCVD), plasma enhanced CVD (PECVD) or flowable CVD (FCVD).

Next, a planarization process, such as a chemical-mechanical polishing (CMP) process may be performed to expose the top of the fins 108a-b, 110a-b. In some embodiments, the planarization process exposes the top of the mask (not shown) disposed on the fins 108a-b and 110a-b. The insulating structure 112 is then recessed by removing portions of the insulating structure 112 located on both sides of each fin 108a-b, 110a-b. The recessed insulating structure 112 may be shallow trench isolation (STI) region.

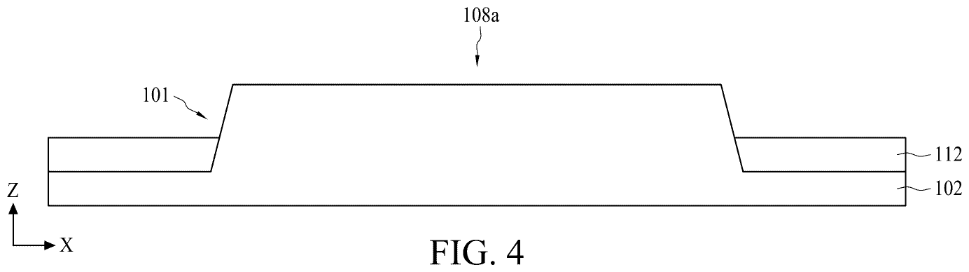

FIG. 4 is a cross-sectional side view of the semiconductor device structure 100, in accordance with some embodiments. In some embodiments, one or more of the fins 108a-b, 110a-b are defined along the X direction, as shown in FIG. 4. The length of the one or more of the fins 108a-b, 110a-b along the X direction may define the dimension of an active region 101 along the X direction. The edges of the one or more of the fins 108a-b, 110a-b along the X direction may be slanted as a result of the process to form the fins 108a-b, 110a-b, as shown in FIG. 4. FIG. 4 illustrates the fin 108a. However, the fin shown in FIG. 4 may be any fin, such as any of the fins 108a-b, 110a-b.

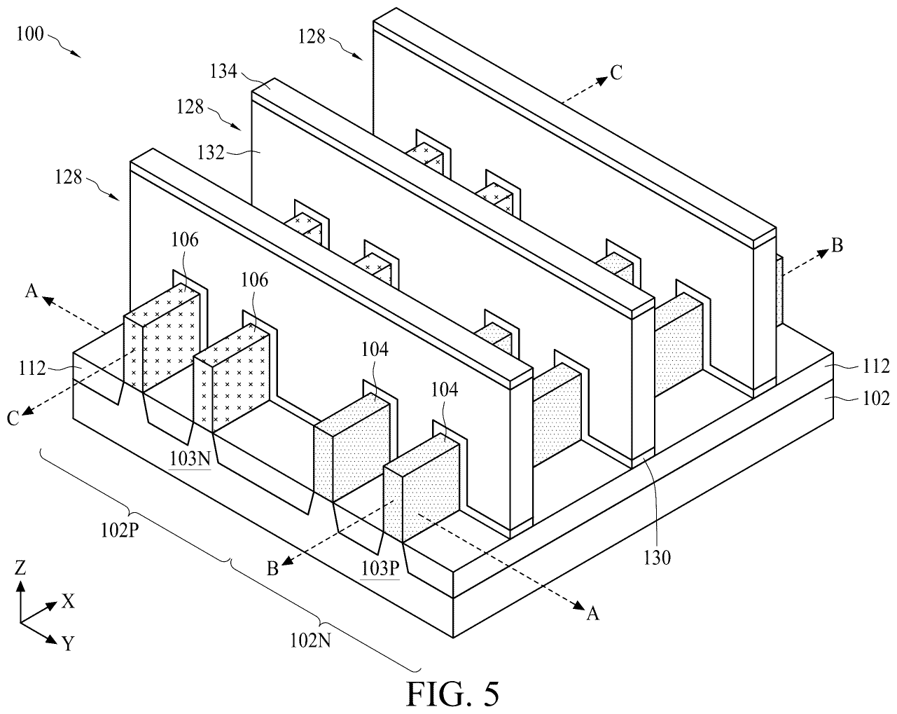

FIG. 5 is a perspective view of the semiconductor device structure 100, in accordance with some embodiments. In FIG. 5, one or more sacrificial gate stacks 128 are formed on a portion of the fins 108a-b, 110a-b. Each sacrificial gate stack 128 may include a sacrificial gate dielectric layer 130, a sacrificial gate electrode layer 132, and a mask structure 134. The sacrificial gate dielectric layer 130 may include one or more layers of dielectric material, such as SiO₂, SiN, a high-K dielectric material, and/or other suitable dielectric material. In some embodiments, the sacrificial gate dielectric layer 130 may be deposited by a CVD process, a sub-atmospheric CVD (SACVD) process, a FCVD process, an ALD process, a PVD process, or other suitable process. The sacrificial gate electrode layer 132 may include polycrystalline silicon (polysilicon). The mask structure 134 may include an oxygen-containing layer and a nitrogen-containing layer. In some embodiments, the sacrificial gate electrode layer 132 and the mask structure 134 are formed by various processes such as layer deposition, for example, CVD (including both LPCVD and PECVD), PVD, ALD, thermal oxidation, e-beam evaporation, or other suitable deposition techniques, or combinations thereof.

The sacrificial gate stacks 128 may be formed by first depositing blanket layers of the sacrificial gate dielectric layer 130, the sacrificial gate electrode layer 132, and the mask structure 134, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the sacrificial gate stacks 128, the fins 108a-b, 110a-b are partially exposed on opposite sides of the sacrificial gate stacks 128. Portions of the insulating structure 112 are exposed as a result of the etch process(s) to form the sacrificial gate stacks 128. While three sacrificial gate stacks 128 are shown in FIG. 4, it can be appreciated that they are for illustrative purpose only and any number of the sacrificial gate stacks 128 may be formed.

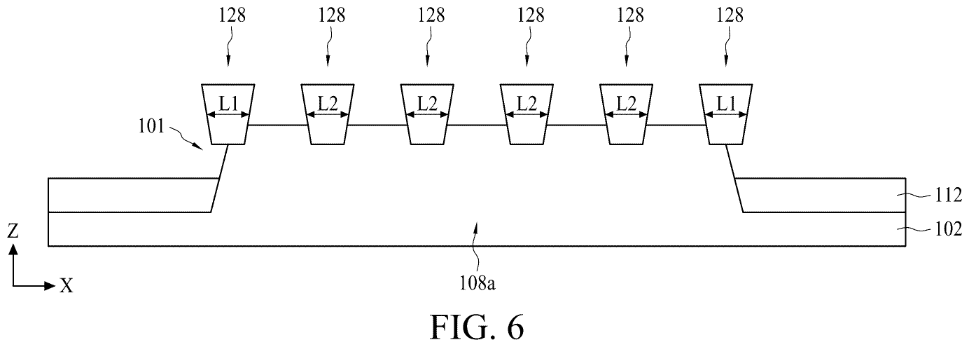

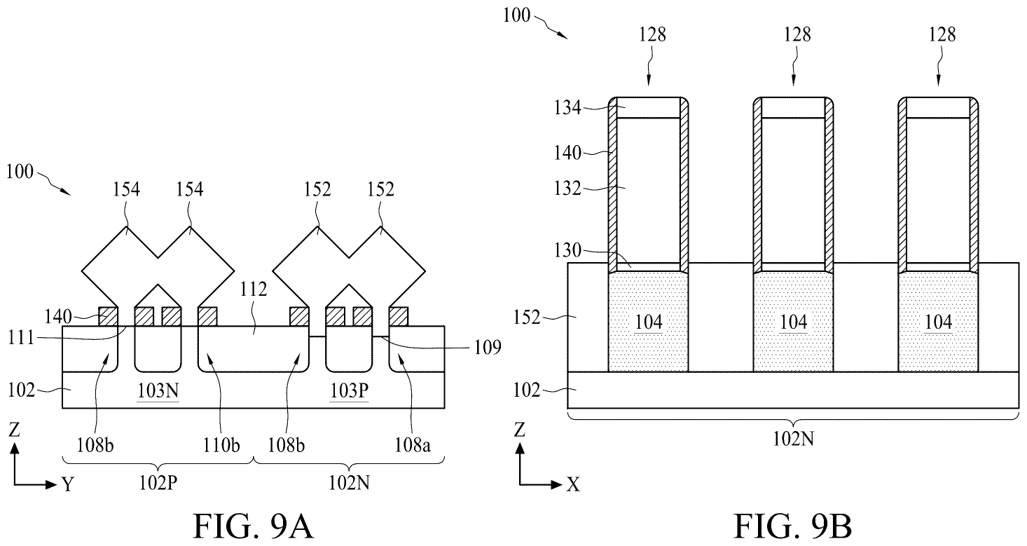

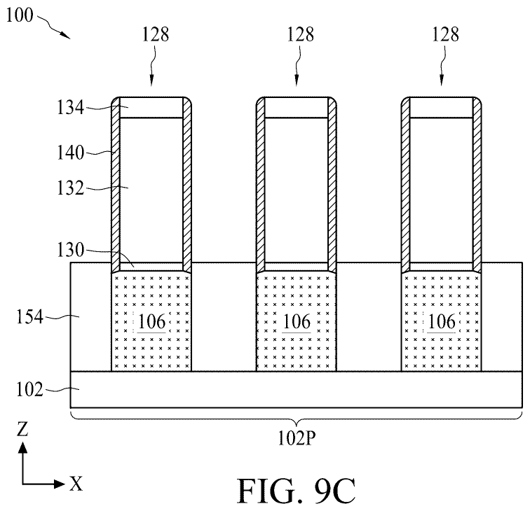

FIG. 6 is a cross-sectional side view of the semiconductor device structure 100, in accordance with some embodiments. As shown in FIG. 6, in some embodiments, a plurality of sacrificial gate stacks 128 are formed in the active region 101. The cross-sectional shape of the sacrificial gate stacks 128 are for illustrative purposes, and the details of the sacrificial gate stack 128 are omitted for clarity. In some embodiments, the sacrificial gate stack 128 has a upside down trapezoid cross-section, as shown in FIG. 6. In some embodiments, the sacrificial gate stack 128 has a rectangular cross-section, as shown in FIG. 5. In some embodiments, the sacrificial gate stacks 128 located at the edges of the active region 101 each has a length L1, and the sacrificial gate stacks 128 located therebetween each has a length L2. In some embodiments, the length L1 is the same as the length L2. The sacrificial gate stacks 128 located at the edges are to cover the edges of the fin 108a (or fins 108a-b and 110a-b). If the edges of the fin 108a is not covered, subsequent process to form source/drain (S/D) regions 152, 154 (FIG. 9A-9C) may form an epitaxial feature at the edge of the fin 108a, which may cause problems during subsequent processes. Thus, in some embodiments, the sacrificial gate stacks 128 located at the edges of the fin 108a may have a longer length L1 to ensure that the edges of the fin 108 are covered. In some embodiments, the length L1 of the edge sacrificial gate stacks 128 located at the edges is greater than the length L2 of the center sacrificial gate stacks 128 located between the two edge sacrificial gate stacks 128. In some embodiments, the center sacrificial gate stacks 128 have the same length L2, as shown in FIG. 6.

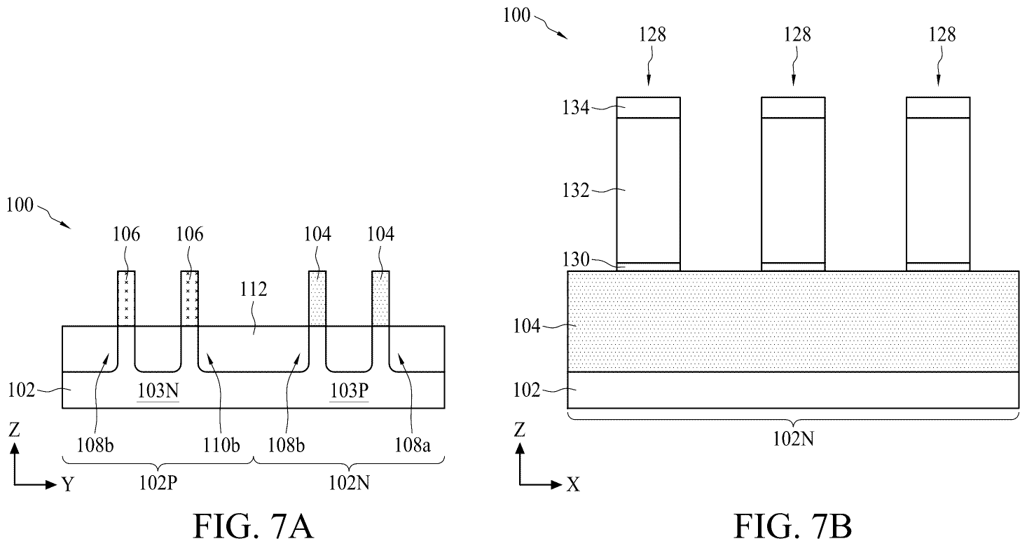

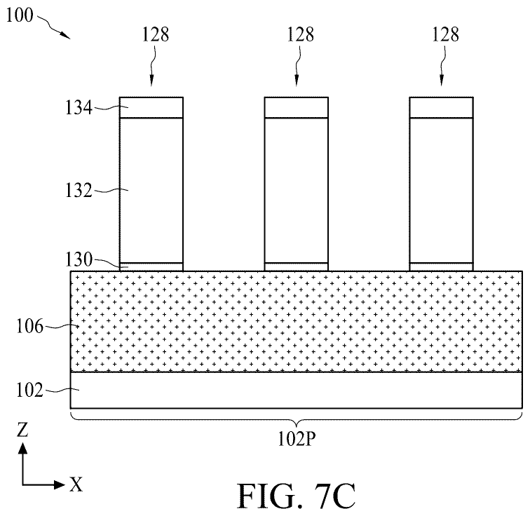

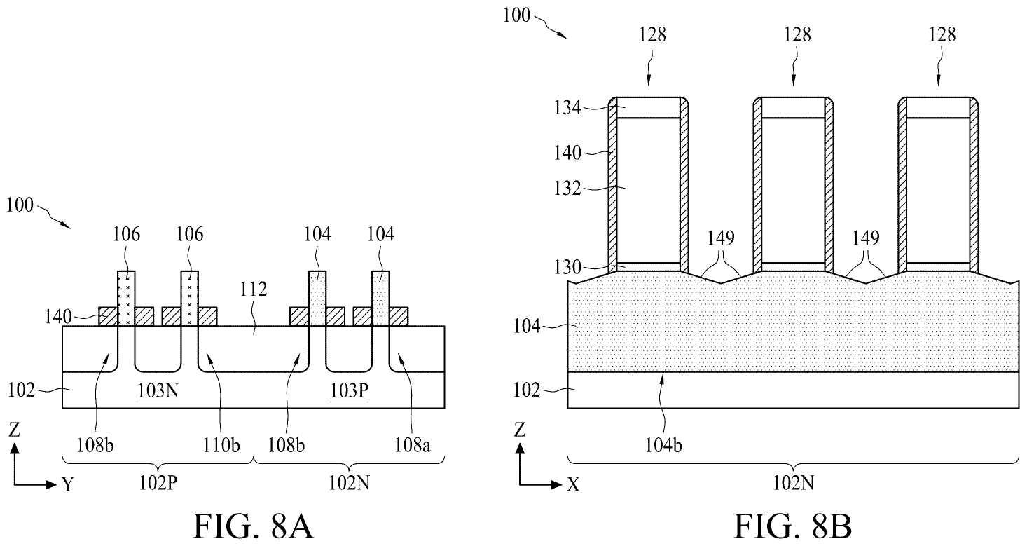

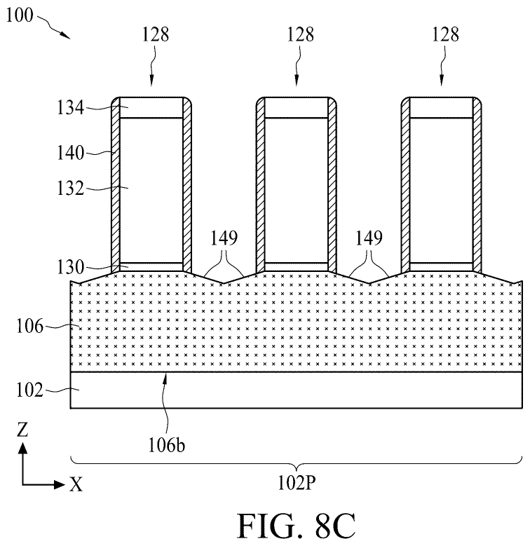

FIGS. 7A, 8A, 9A, and 10A are cross-sectional side views of various stages of manufacturing the semiconductor device structure 100 of FIG. 5 taken along line A-A, in accordance with some embodiments. FIGS. 7B, 8B, 9B, and 10B are cross-sectional side views of various stages of manufacturing the semiconductor device structure 100 of FIG. 5 taken along line B-B, in accordance with some embodiments. FIGS. 7C, 8C, 9C, and 10C, are cross-sectional side views of various stages of manufacturing the semiconductor device structure 100 of FIG. 5 taken along line C-C, in accordance with some embodiments. FIGS. 7A-7C illustrate a stage after the sacrificial gate stacks 128 are formed on a portion of the fins 108a-b, 110a-b. In FIGS. 8A-8C, a spacer 140 is formed on the sacrificial gate stacks 128 and the exposed portions of the first and second semiconductor layers 104, 106. The spacer 140 may be conformally deposited on the exposed surfaces of the semiconductor device structure 100. The conformal spacer 140 may be formed by ALD or any suitable processes. An anisotropic etch is then performed on the spacer 140 using, for example, RIE. During the anisotropic etch process, most of the spacer 140 is removed from horizontal surfaces, such as tops of the sacrificial gate stacks 128 and tops of the fins 108a-b, 110a-b, leaving the spacer 140 on the vertical surfaces, such as on opposite sidewalls of the sacrificial gate stacks 128. The spacers 140 may partially remain on opposite sidewalls of the fins 108a-b, 110a-b, as shown in FIG. 8A. In some embodiments, the spacers 140 formed on the S/D regions of the fins 108a-b, 110a-b are fully removed.

The spacer 140 may be made of a dielectric material such as silicon oxide (SiO₂), silicon nitride (Si₃N₄), silicon carbide (SiC), silicon oxynitride (SiON), silicon carbon-nitride (SiCN), silicon oxycarbide (SiOC), silicon oxycarbonitride (SiOCN), air gap, and/or any combinations thereof. In some embodiments, the spacer 140 include one or more layers of the dielectric material discussed above.

In various embodiments where the spacer 140 includes multiple layers, the top portion of the fins 108a-b, 110a-b not covered by the sacrificial gate stacks 128 may have a taper profile 149, as shown in FIGS. 8B, 8C. The taper profile 149 may be formed as a result of multiple exposure of the first and second semiconductor layers 104, 106 to etchants used during formation of the spacer 140. The taper profile 149 between adjacent sacrificial gate stacks 128 forms a shallow V-shaped top surface in the first and second semiconductor layers 104, 106, respectively.

In FIGS. 9A-9C, the first and second semiconductor layers 104, 106 of the fins 108a-b, 110a-b not covered by the sacrificial gate stacks 128 and the spacers 140 are recessed, and S/D regions 152, 154 are formed. In this disclosure, a source region and a drain region are interchangeably used, and the structures thereof are substantially the same. Furthermore, source/drain region(s) may refer to a source or a drain, individually or collectively dependent upon the context. For devices in the NMOS region 102N, each S/D region 152 may include one or more layers of Si, SiP, SiC, SiCP, SiAs, or a group III-V material (InP, GaAs, AlAs, InAs, InAlAs, InGaAs). In some embodiments, each S/D region 152 includes two or more layers of Si, SiP, SiC, SiCP or the group III-V material, and each layer may have a different silicon concentration. Each S/D region 152 may include N-type dopants, such as phosphorus (P), arsenic (As), or other suitable N-type dopants. The S/D regions 152 may be formed by any suitable method, such as CVD, CVD epitaxy, MBE, or other suitable method. The S/D regions 152 may be formed on the exposed surface of the fins 108a-b on both sides of each sacrificial gate stack 128, as shown in FIG. 9B. In some embodiments, the portions of the first semiconductor layer 104 on both sides of each sacrificial gate stack 128 are completely removed, and the S/D regions 152 are formed on the P-well region 103P of the fins 108a-b. The S/D regions 152 may grow both vertically and horizontally to form facets, which may correspond to crystalline planes of the material used for the substrate 102. In some embodiments, the S/D regions 152 formed on the P-well region 103P of the fins 108a and 108b are merged, as shown in FIG. 9A. The S/D regions 152 may each have a top surface at a level higher than a top surface of the first semiconductor layer 104, as shown in FIG. 9B.

For devices in the PMOS region 102P, each S/D region 154 may include one or more layers of Si, SiGe, SiGeB, Ge, or a group III-V material (InSb, GaSb, InGaSb), and each layer may have a different silicon or germanium concentration. Each S/D region 154 may include P-type dopants, such as boron (B) or other suitable P-type dopants. In some embodiments, the S/D regions 152 in the NMOS region 102N and the S/D regions 154 in the PMOS region 102P are both Si. In some embodiments, the S/D regions 152 in the NMOS region 102N are Si and the S/D regions 154 in the PMOS region 102P are SiGe. The S/D regions 154 may be formed by any suitable method, such as CVD, CVD epitaxy, MBE, or other suitable method. In some embodiments, the portions of the second semiconductor layer 106 on both sides of each sacrificial gate stack 128 are completely removed, and the S/D regions 154 are formed on the N-well region 103N of the fins 110a-b. The S/D regions 154 may grow both vertically and horizontally to form facets, which may correspond to crystalline planes of the material used for the substrate 102. In some embodiments, the S/D regions 154 formed on the N-well region 103N of the fins 110a and 110b are merged, as shown in FIG. 9A. The S/D regions 154 may each have a top surface at a level higher than a top surface of the second semiconductor layer 106, as shown in FIG. 9C.

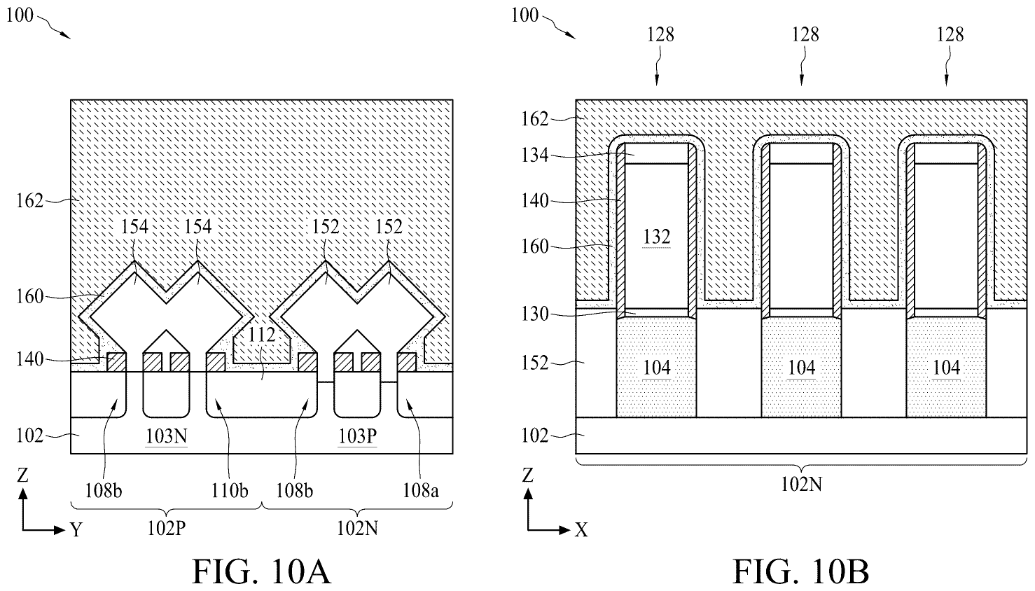

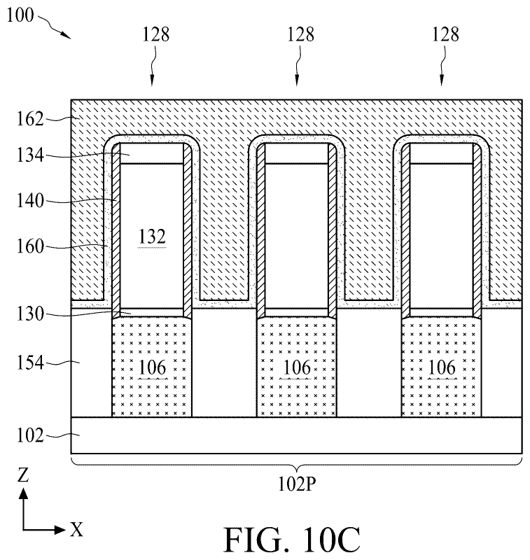

In FIGS. 10A-10C, a contact etch stop layer (CESL) 160 is conformally formed on the exposed surfaces of the semiconductor device structure 100. The CESL 160 covers the sidewalls of the sacrificial gate stacks 128, the insulating structure 112, and the S/D regions 152, 154. The CESL 160 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique.

Next, an interlayer dielectric (ILD) layer 162 is formed on the CESL 160. The materials for the ILD layer 162 may include compounds comprising Si, O, C, and/or H, such as SiOCH, oxide formed using tetraethylorthosilicate (TEOS), un-doped silicate glass, silicon oxide, or doped silicon oxide such as borophosphosilicate glass (BPSG), fused silica glass (FSG), phosphosilicate glass (PSG), boron doped silicon glass (BSG), and/or other suitable dielectric materials. The ILD layer 162 may be deposited by a PECVD process or other suitable deposition technique.

After the formation of the ILD layer 162, a planarization process is performed to expose the sacrificial gate electrode layer 132. The planarization process may be any suitable process, such as a CMP process. The planarization process removes portions of the ILD layer 162 and the CESL 160 disposed on the sacrificial gate stacks 128. The planarization process may also remove the mask structure 134.

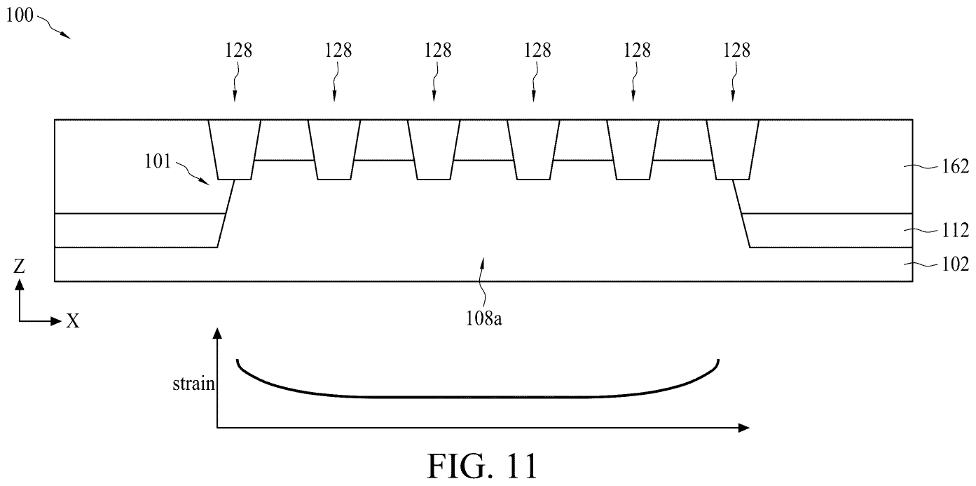

FIG. 11 is a cross-sectional side view of the semiconductor device structure 100, in accordance with some embodiments. The CESL 160, the spacer 140, the mask structure 134, and the S/D regions 152, 154 are omitted for clarity in FIG. 11. In some embodiments, each sacrificial gate stack 128 is under a strain caused by the ILD layer 162, and the edge sacrificial gate stacks 128 are under the highest strain, because the maximum strain occurs at the interface between the ILD layer 162 and the fin 108a. The chart below the semiconductor device structure 100 shows the strain applied by the ILD layer 162 on the corresponding sacrificial gate stacks 128. The edge sacrificial gate stacks 128 have the highest strain, and the strain decreases in a direction away from the edge of the fin 108a. In some embodiments, the longer the ILD layer 162 along the X direction, the higher the strain applied by the ILD layer 162 on the sacrificial gate stacks 128.

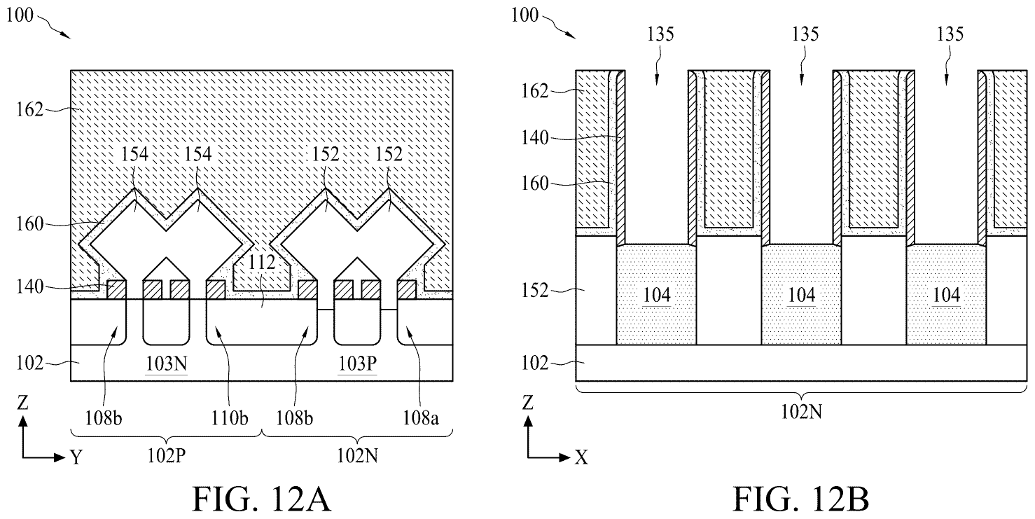

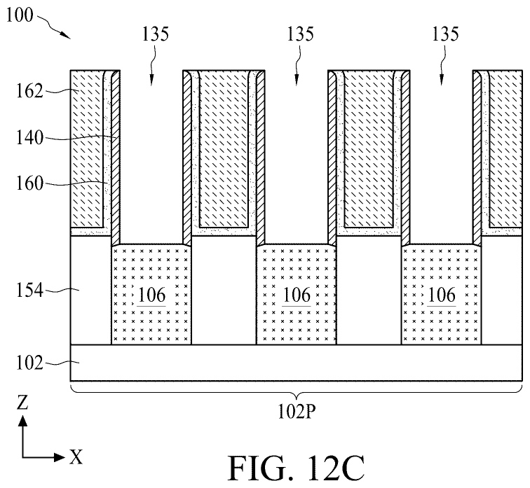

FIGS. 12A, 12B, and 12C are cross-sectional side views of various stages of manufacturing the semiconductor device structure 100 of FIG. 5 taken along lines A-A, B-B, and C-C, respectively, in accordance with some embodiments. In FIGS. 12A-12C, the mask structure 134 (if not removed during CMP process), the sacrificial gate electrode layers 132 (FIG. 10B), and the sacrificial gate dielectric layers 130 (FIG. 10B) are removed to form openings 135. The sacrificial gate electrode layers 132 and the sacrificial gate dielectric layers 130 may be removed by one or more etch processes, such as dry etch process, wet etch process, or a combination thereof. The one or more etch processes selectively remove the sacrificial gate electrode layers 132 and the sacrificial gate dielectric layers 130 without substantially affecting the spacer 140, the CESL 160, and the ILD layer 162. The removal of the sacrificial gate electrode layers 132 and the sacrificial gate dielectric layers 130 exposes a top portion of the first and second semiconductor layers 104, 106 in the channel region.

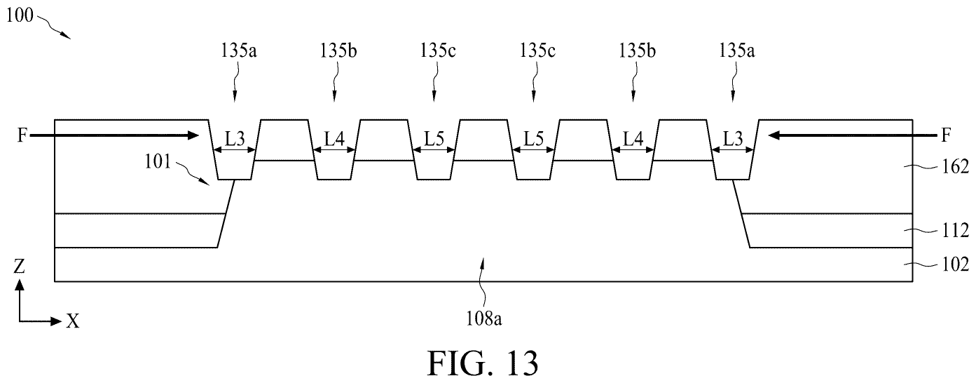

FIG. 13 is a cross-sectional side view of the semiconductor device structure 100, in accordance with some embodiments. The CESL 160, the spacer 140, the mask structure 134, and the S/D regions 152, 154 are omitted for clarity in FIG. 13. As shown in FIG. 13, the sacrificial gate stacks 128 are removed, and the openings 135a-c are formed. The openings 135a-c may have lengths L3, L4, L5 along the X direction, respectively. As described above, the sacrificial gate stacks 128 are under strain from the ILD layer 162. In other words, a force F is exserted on the openings 135a-c by the ILD layer 162. Thus, in some embodiments, the removal of the sacrificial gate stacks 128 causes the openings 135a-b at locations of high strain to shrink along the X direction. For example, the length L3 of the openings 135a formed by removing the edge sacrificial gate stacks 128 may be substantially smaller than the length L1 (FIG. 6) of the edge sacrificial gate stacks 128, and the length L4 of the openings 135b formed by removing the sacrificial gate stacks 128 adjacent the edge sacrificial gate stacks 128 may be substantially smaller than the length L2 (FIG. 6) of the sacrificial gate stacks 128 adjacent the edge sacrificial gate stacks 128. In some embodiments, the length L5 of the openings 135c in the center of the active region 101 may be substantially the same and may be substantially the same as the length L2 (FIG. 6) of the center sacrificial gate stacks 128, because the strain is the lowest at such locations compared to the locations of the openings 135a, 135b. In other words, the openings closer to the portion of the ILD layer outside of the active region 101 have a greater shrinkage.

In some embodiments, the openings 135c all have the length L5, which is greater than the length L4 of the openings 135b as a result of the higher strain on the openings 136b. In some embodiments, the length L1 (FIG. 6) of the edge sacrificial gate stacks 128 is the same as the length L2 (FIG. 6) of the center sacrificial gate stacks 128, and the length L3 is smaller than the length L4 as a result of the higher strain on the openings 135a. In some embodiments, the length L1 (FIG. 6) of the edge sacrificial gate stacks 128 is greater than the length L2 (FIG. 6) of the center sacrificial gate stacks 128, and the length L3 is greater than or equal to the length L4.

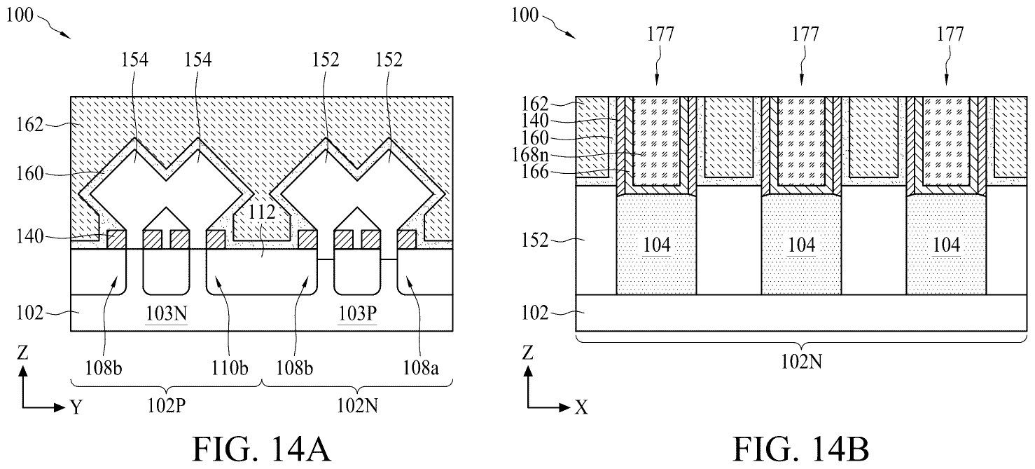

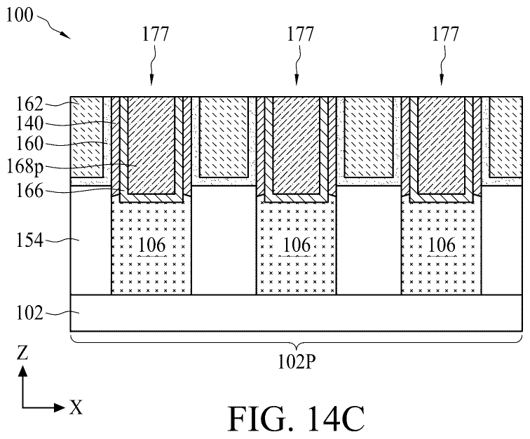

In FIGS. 14A-14C, replacement gate structures 177 are formed. The replacement gate structure 177 may include a gate dielectric layer 166 and a gate electrode layer 168p, 168n formed on the gate dielectric layer 166. As can be seen in FIGS. 14B and 14C, the gate dielectric layer 166 is formed on the first and second semiconductor layers 104, 106. The gate dielectric layer 166 may include one or more dielectric layers and may include the same material(s) as the sacrificial gate dielectric layer 130. In some embodiments, the gate dielectric layers 166 may be deposited by one or more ALD processes or other suitable processes. The gate electrode layer 168p, 186n may include one or more layers of electrically conductive material, such as polysilicon, aluminum, copper, titanium, tantalum, tungsten, cobalt, molybdenum, tantalum nitride, nickel silicide, cobalt silicide, TiN, WN, AlTi, AlTiO, AlTiC, AlTiN, TaCN, TaC, TaSiN, metal alloys, other suitable materials, and/or combinations thereof. For devices in the NMOS region 102N, the gate electrode layer 168n may include an N-type material, such as AlTiO, AlTiC, or a combination thereof. For devices in the PMOS region 102P, the gate electrode layer 168p may include a P-type material, such as AlTiO, AlTiC, AlTiN, or a combination thereof. The gate electrode layers 168n, 168p may be formed by PVD, CVD, ALD, electro-plating, or other suitable method. The gate electrode layers 168n, 168p may be formed at different times using one or more masks. For example, in some embodiments, the gate electrode layers 168p are formed over the fins 108a-b, 110a-b, and an etch process is performed to remove the portions of the gate electrode layers 168p located over the fins 108a-b. Next, the gate electrode layers 168n are formed over the fins 108a-b and the gate electrode layers 168p. A planarization process is then performed to remove portions of the gate electrode layers 168n to expose the gate electrode layers 168p.

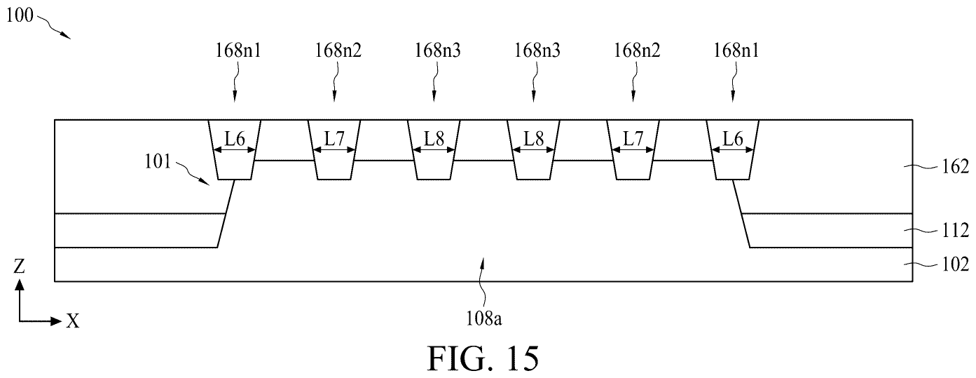

FIG. 15 is a cross-sectional side view of the semiconductor device structure 100, in accordance with some embodiments. The CESL 160, the spacer 140, the gate dielectric layer 166, and the S/D regions 152, 154 are omitted for clarity in FIG. 15. As shown in FIG. 15, a plurality of gate electrode layers 168n are formed in the active region 101. The gate electrode layers 168n1 are located at the edges of the fin 108a, the gate electrode layers 168n2 are located adjacent the gate electrode layers 168n1, and the gate electrode layers 168n3 are located between the gate electrode layers 168n2. In some embodiments, each gate electrode layer 168n1 has a gate length L6, each gate electrode layer 168n2 has a gate length L7, and each gate electrode layer 168n3 has a gate length L8. As described above, the gate length L6 may be the smallest, the gate length L7 may be greater than the gate length L6, and the gate length L8 may be greater than the gate length L7 as a result of the force F applied by the ILD layer 162. In some applications, such as radio frequency (RF) devices, active devices having mismatched gate lengths can lead to a mismatch in gate resistance, gate to environment total capacitance, and maximum power gain cut-off frequency. Thus, in some embodiments, the plurality of gate electrode layers 168n3 having uniform gate length L8 are active gates, while the gate electrode layers 168n1, 168n2 located at the periphery of the active region 101 are dummy gates. The term “dummy gates” may refer to gate electrode layers that are not a functional part of an active or passive device and may be electrically isolated from other structures. By making the gate electrode layers 168n3 having the uniform gate length active gates, the mismatch in gate resistance, gate to environment total capacitance, and maximum power gain cut-off frequency are reduced.

In some embodiments, the length L1 is substantially greater than the length L2 in order to cover the edge of the fin 108a, as described in FIG. 6. As a result, the gate length L6 may be greater than the gate lengths L7, L8. The gate length L6 may be 1/10 to 10 times the length L8, and the gate length L7 is less than the gate length L8. In some embodiments, a distance between the gate electrode layer 168n1 and the gate electrode layer 168n2 is about 1/10 to about 10 times the distance between adjacent gate electrode layers 168n3.

In some embodiments, the gate electrode layers 168n1 include different materials than the gate electrode layers 168n2, 168n3. For example, the gate electrode layers 168n1 includes the same material as the sacrificial gate electrode layer 132. The replacement gate process is not performed on the sacrificial gate electrode layers 132 located at the edge of the active region 101. In other words, the gate electrode layers 168n1 are the sacrificial gate electrode layers 132. During the process to remove the sacrificial gate electrode layers 132 shown in FIGS. 12B and 12C, a mask (not shown) may be formed on the sacrificial gate electrode layers 132 located at the edge of the active region 101. In some embodiments, the gate electrode layers 168n2 include the same materials as the gate electrode layers 168n3. In other words, the gate electrode layers 168n2, 168n3 are formed as a result of the replacement gate process, and the gate electrode layers 168n2, 168n3 include the same materials. In some embodiments, each of the gate electrode layers 168n1 includes polysilicon, and the each of the gate electrode layers 168n2, 168n3 includes a Ti, Ta, TiN, TaN, TiON, tungsten, or other suitable material.

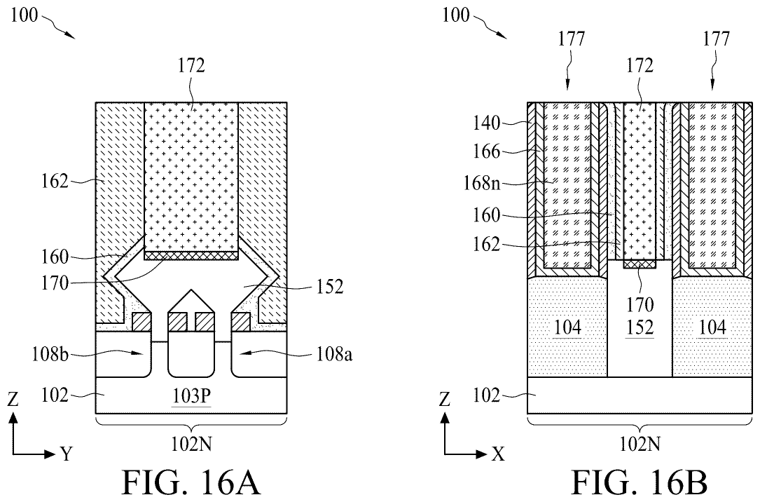

FIGS. 16A and 16B are cross-sectional side views of various stages of manufacturing the semiconductor device structure 100 of FIG. 5 taken along lines A-A and B-B, respectively, in accordance with some embodiments. In some embodiments, a conductive feature 172 is formed in the ILD layer 162 and the CESL 160, and a silicide layer 170 is formed between the conductive feature 172 and the S/D region 152 or the S/D region 154. The conductive feature 172 may include any suitable electrically conductive material. In some embodiments, the conductive feature 172 may include tungsten (W), platinum (Pt), tantalum (Ta), titanium (Ti), copper (Cu), cobalt (Co), ruthenium (Ru), rhodium (Rh), iridium (Ir), molybdenum (Mo), or other suitable metal. The silicide layer 170 may include any suitable material, such as titanium silicide, cobalt silicide, nickel silicide, tungsten silicide, copper silicide, or molybdenum silicide.

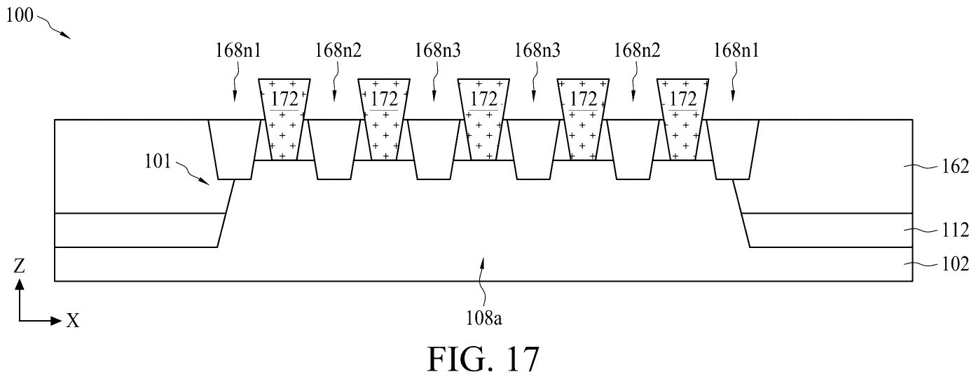

FIG. 17 is a cross-sectional side view of the semiconductor device structure 100, in accordance with some embodiments. The CESL 160, the spacer 140, the gate dielectric layer 166, and the S/D regions 152, 154 are omitted for clarity in FIG. 17. As shown in FIG. 17, the conductive features 172 are formed between adjacent gate electrode layers 168n1-3. In some embodiments, the conductive features 172 are formed between the gate electrode layer 168n1 and the gate electrode layer 168n2, and the conductive features 172 are dummy conductive features that are not a functional part of an active or passive device and may be electrically isolated from other structures.

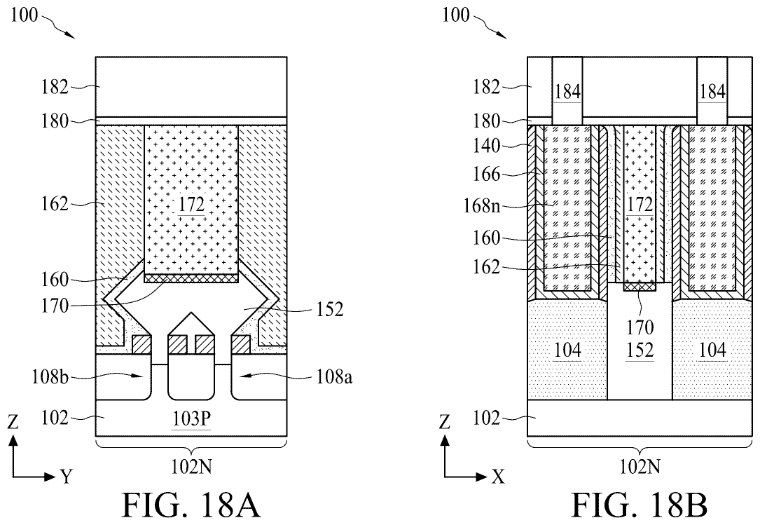

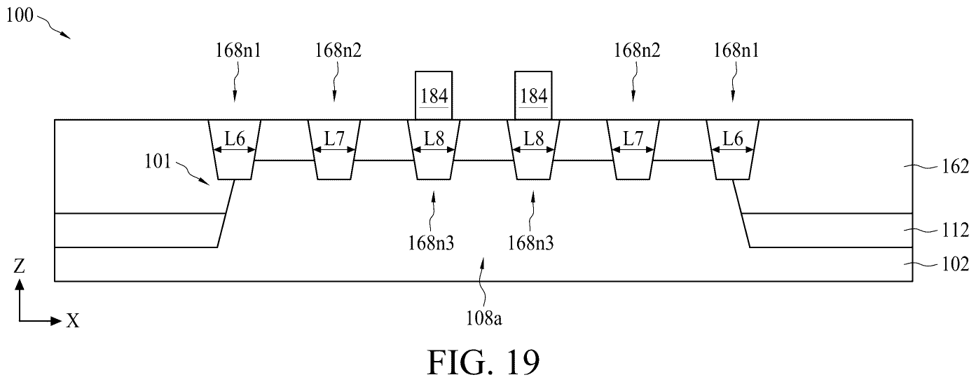

FIGS. 18A and 18B are cross-sectional side views of various stages of manufacturing the semiconductor device structure 100 of FIG. 5 taken along lines A-A and B-B, respectively, in accordance with some embodiments. As shown in FIGS. 18A and 18B, an etch stop layer 180 is deposited on the semiconductor device structure 100, and another ILD layer 182 is deposited on the etch stop layer 180. The etch stop layer 180 may include the same material as the CESL 160, and the ILD layer 182 may include the same material as the ILD layer 162. Next, conductive features 184 are formed in the ILD layer 182 and the etch stop layer 180. The conductive features 184 may include any suitable electrically conductive material, such as a metal. In some embodiments, the conductive features 184 are formed over the active gate electrode layers 168n, such as gate electrode layers 168n3 (FIG. 19).

FIG. 19 is a cross-sectional side view of the semiconductor device structure 100, in accordance with some embodiments. The CESL 160, the spacer 140, the gate dielectric layer 166, the S/D regions 152, 154, the conductive features 172, the etch stop layer 180, and the ILD layer 182 are omitted for clarity in FIG. 18. As shown in FIG. 19, the conductive features 184 are formed over the gate electrode layers 168n3 but not over the gate electrode layers 168n1, 168n2. Because the gate electrode layers 168n1, 168n2 are dummy gates, the conductive features 184 are not formed thereover. Instead, the etch stop layer 180 (FIG. 18A) is in direct contact with the top surfaces of the gate electrode layers 168n1, 168n2.

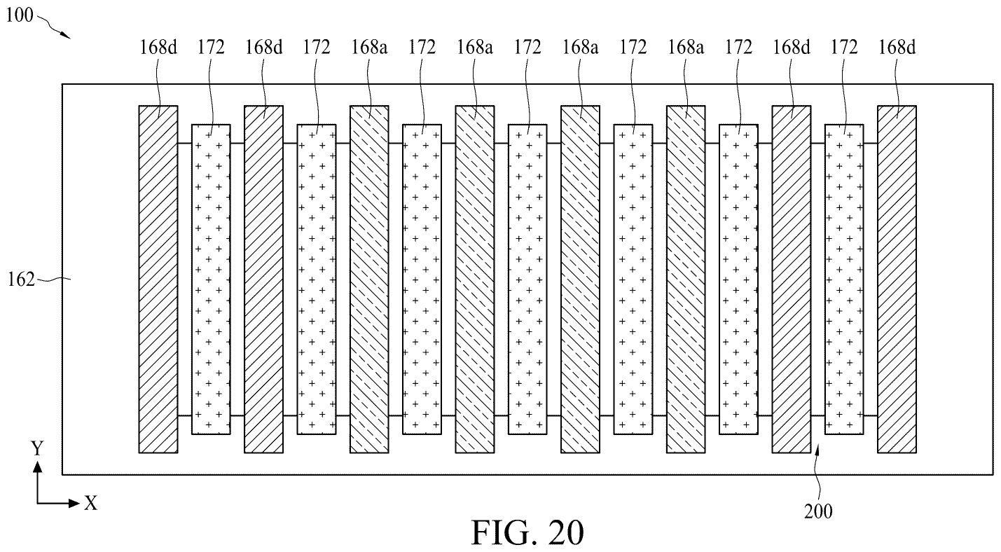

FIGS. 20, 21, and 22 are top view of the semiconductor device structure 100, in accordance with some embodiments. The CESL 160, the spacer 140, the gate dielectric layer 166, the S/D regions 152, 154, the conductive features 172, the etch stop layer 180, the ILD layer 182, and the conductive features 184 are omitted for clarity in FIGS. 20-22. As shown in FIG. 20, the semiconductor device structure 100 includes a fin 200, which may be any of the fins 108a-b, 110a-b. In the active region 101, the semiconductor device structure 100 includes a plurality of active gate electrode layers 168a disposed between at least four dummy gate electrode layers 168d with at least two dummy gate electrode layers 168d on each side of the plurality of active gate electrode layers 168a. The number of the active gate electrode layers 168a may be any suitable number, such as from one to about 100. In some embodiments, the outermost dummy gate electrode layers 168d are the gate electrode layers 168n1 (FIG. 15) having the gate length L6, the dummy gate electrode layer 168d located adjacent the outermost dummy gate electrode layers 168d are the gate electrode layers 168n2 (FIG. 15) having the gate length L7, and the active gate electrode layers 168a are the gate electrode layers 168n3 (FIG. 15) having the gate length L8. Because the active gate electrode layers 168a include uniform gate length L8, mismatch in gate resistance, gate to environment total capacitance, and maximum power gain cut-off frequency are reduced.

In some embodiments, as described above, the gate electrode layers 168n1 and the gate electrode layers 168n2 may include different materials. Thus, the dummy gate electrode layers 168d may include different materials. For example, a first dummy gate electrode layer 168d located on a first side of the active region 101 includes a first material, and a second dummy gate electrode layer 168d located adjacent the first dummy gate electrode layer 168d includes a second material different from the first material. In some embodiments, the first material is polysilicon, and the second material is a metal.

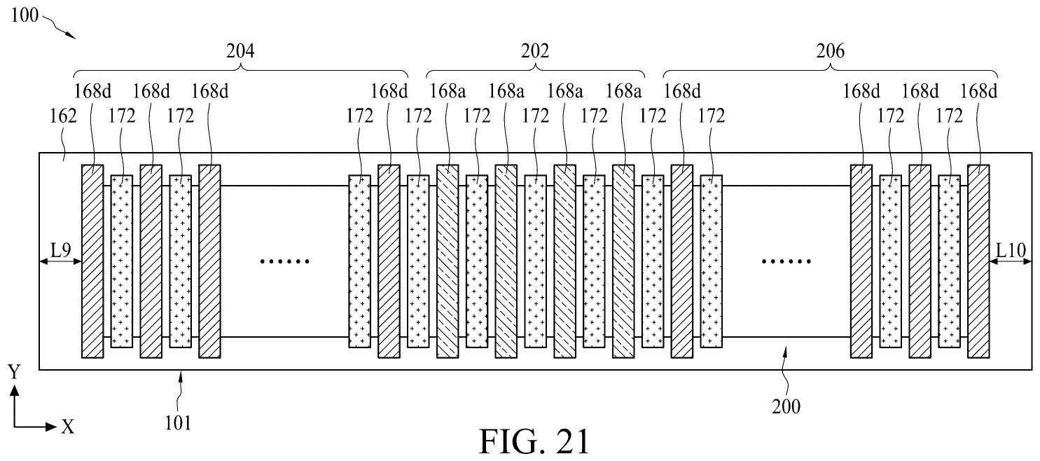

In some embodiments, as shown in FIG. 21, the active region 101 includes a center region 202, a first side region 204, and a second side region 206. The center region 202 includes the active gate electrode layers 168a, the first side region 204 includes a first number of dummy gate electrode layers 168d, and the second side region 206 includes a second number of dummy gate electrode layers 168d. The portion of the ILD layer 162 located adjacent the first side region 204 has a length L9 along the X direction, and the portion of the ILD layer 162 located adjacent the second side region 206 has a length L10 along the X direction. Each portion of the ILD layer 162 having the lengths L9, L10 is continuous and not interrupted by any features, such as gate electrode layers in the active region adjacent the active region 101 or dummy gate electrode layers in an isolation region surrounding the active region 101.

In some embodiments, the lengths L9, L10 determine the first number and the second number of the dummy gate electrode layers 168d. The force F (FIG. 13) is based on the length of the portion of the ILD layer 162 along the X direction adjacent the active region 101. The longer the length, the greater the force F. With the greater force F, more openings 135 (FIG. 13) may shrink along the X direction, leading to more gate electrode layers having smaller gate length. In some embodiments, the gate electrode layers having the smaller gate length are designated as dummy gate electrode layers in order to reduce mismatch in gate resistance, gate to environment total capacitance, and maximum power gain cut-off frequency. Referring back to FIG. 21, in some embodiments, the length L9 determines the first number of dummy gate electrode layers 168d in the first side region 204, and the length L10 determines the second number of dummy gate electrode layers 168d in the second side region 206. The longer the length L9, the greater the first number, and the longer the length L10, the greater the second number. For example, in one embodiment, the length L9 is about 100 nm, and the first number is one. In another embodiment, the length L9 is about 1000 nm, and the first number is 20. A similar relationship may be found between the length L10 and the second number of dummy gate electrode layers 168d in the second side region 206. In some embodiments, the length L9 and the first number have a positive relationship, and the length L10 and the second number have a positive relationship. In some embodiments, the length L9 is the same as the length L10, and the first number is the same as the second number. In some embodiments, the length L9 is different from the length L10, and the first number is different from the second number. For example, the length L9 is greater than the length L10, and the first number is greater than the second number.

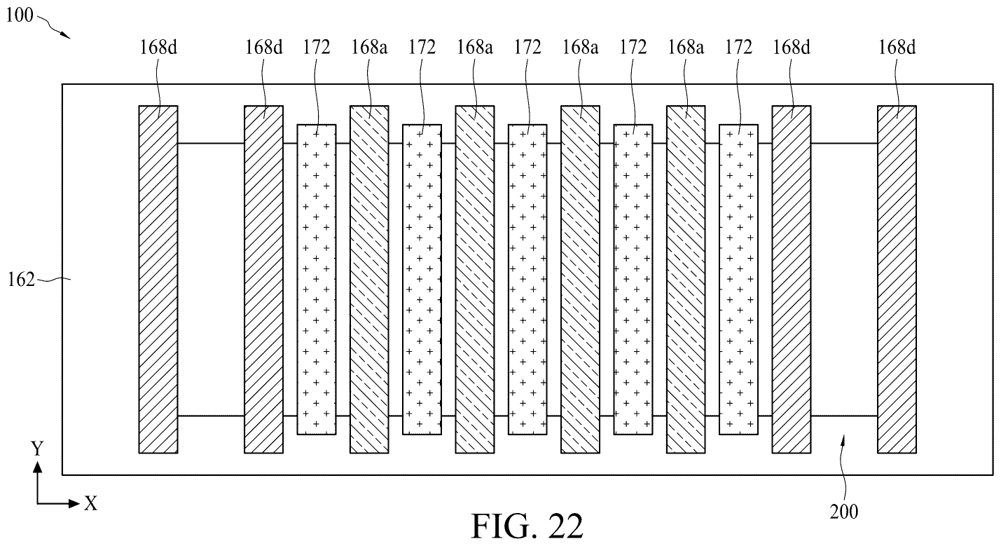

In some embodiments, as shown in FIG. 22, the conductive features 172 located between dummy gate electrode layers 168d are not present, because the S/D regions 152, 154 located adjacent the dummy gate electrode layers 168d are dummy S/D regions. Thus, there is no need to provide an electrical path to the dummy S/D regions. In some embodiments, the conductive features 172 are formed between dummy gate electrode layers 168d, as shown in FIG. 20, and the conductive features 172 are formed to help with loading effect.

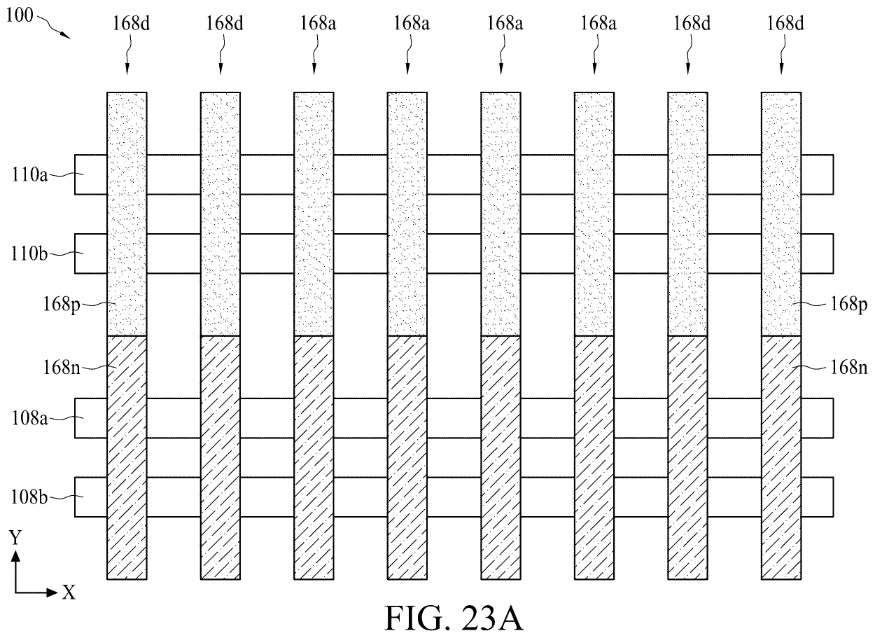

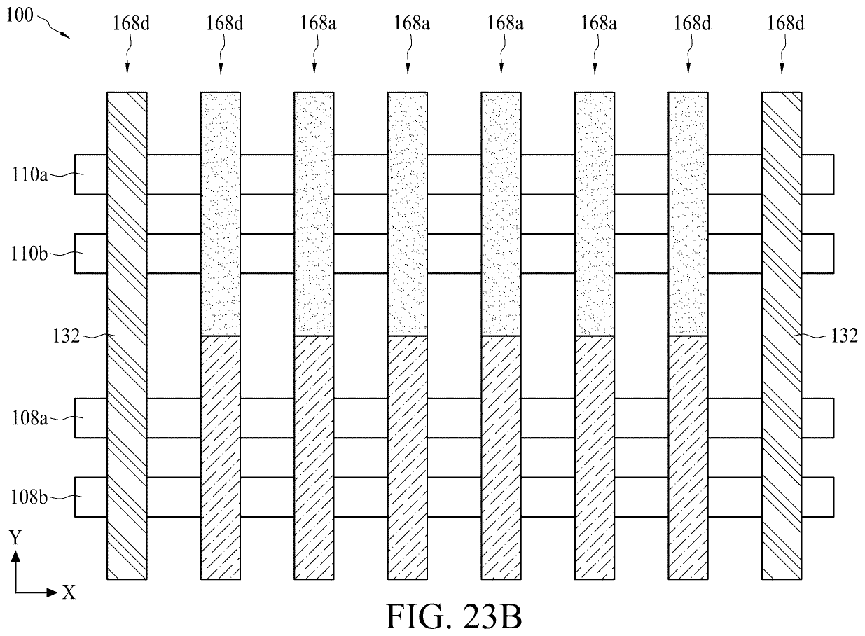

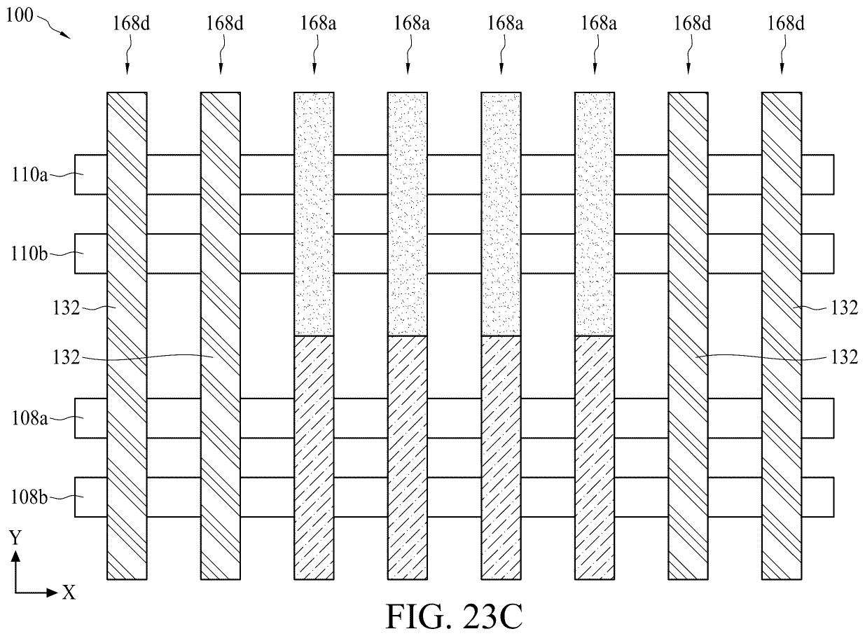

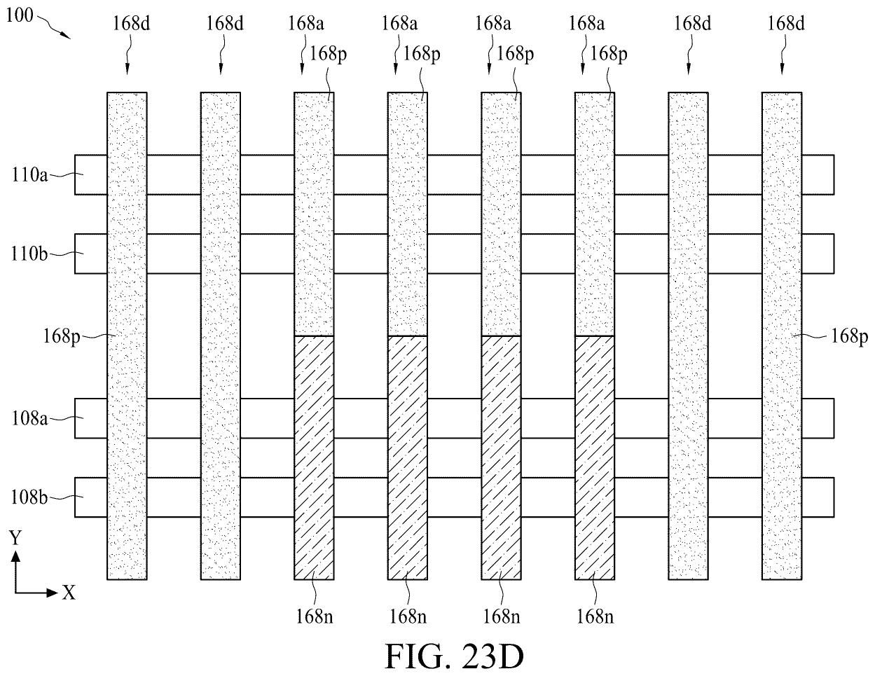

FIGS. 23A, 23B, 23C, and 23D are top views of the semiconductor device structure 100, in accordance with some embodiments. Various components of the semiconductor device structure 100 are omitted in FIGS. 23A-23D for clarity. As shown in FIG. 23A, the semiconductor device structure 100 includes the fins 108a-b, 110a-b, a plurality of active gate electrode layers 168a, and a plurality of dummy gate electrode layers 168d. In some embodiments, each active gate electrode layer 168a and dummy gate electrode layer 168d includes the gate electrode layer 168p disposed over the fins 110a-b and the gate electrode layer 168n disposed over the fins 108a-b.

As shown in FIG. 23B, in some embodiments, the outermost dummy gate electrode layers 168d are the sacrificial gate electrode layers 132, because a mask (not shown) is formed on the outermost sacrificial gate electrode layers 132 during the replacement gate process described in FIGS. 12A-12C.

As shown in FIG. 23C, in some embodiments, all of the dummy gate electrode layers 168d are the sacrificial gate electrode layers 132. A mask (not shown) is formed on all of the sacrificial gate electrode layers 132 that are designated to be dummy gate electrode layers 168d during the replacement gate process described in FIG. 12A-12C.

As shown in FIG. 23D, in some embodiments, all of the dummy gate electrode layers 168d include the gate electrode layers 168p (or the gate electrode layers 168n) but not the gate electrode layers 168n (or the gate electrode layers 168p). During the formation of the gate electrode layers 168n, 168p, after the formation of the gate electrode layers 168p, a mask (not shown) may be formed over the gate electrode layers 168p that are designated to be dummy gate electrode layers 168d. The portions of the gate electrode layers 168p that are designated to be dummy gate electrode layers 168d disposed over the fins 108a-b are not removed during the removal of the portions of the gate electrode layers 168p that are designated to be active gate electrode layers 168a disposed over the fins 108a-b.

The embodiments shown in FIGS. 23A-23D may be combined with each other or with the embodiments shown in FIGS. 20-22.

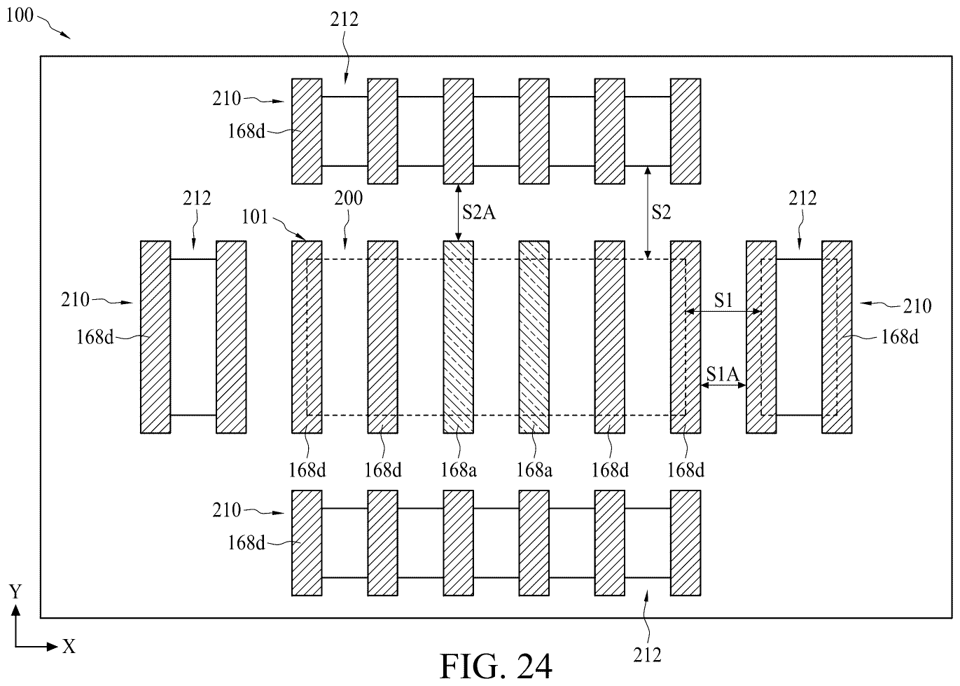

FIG. 24 is a top view of the semiconductor device structure 100, in accordance with some embodiments. As shown in FIG. 24, the semiconductor device structure 100 includes the active region 101 surrounded by dummy regions 210. Each dummy region 210 includes a fin 212 and one or more dummy gate electrode layers 168d. In some embodiments, the fins 212 aligned with the fin 200 along the X direction are part of the fin 200. As shown in FIG. 24, the active region 101 includes one or more active gate electrode layers 168a, and the active gate electrode layers 168a are disposed between four dummy gate electrode layers 168d with at least two on each side.

In some embodiments, a distance S1 is between the centerline of the outermost dummy gate electrode layer 168d and the centerline of the adjacent dummy gate electrode layer 168d of the adjacent dummy region 210 along the X direction, a distance SIA is between the outer edge of the outermost dummy gate electrode layer 168d and the outer edge of the adjacent dummy gate electrode layer 168d of the adjacent dummy region 210 along the X direction, a distance S2 is between the fin 200 and the fin 212 along the Y direction, and a distance S2A is between active gate electrode layer 168a and the adjacent dummy gate electrode layer 168d of the adjacent dummy region 210 along the Y direction. The distance SIA may be the length L9, L10 of the portions of the ILD layer 162 shown in FIG. 21. In some embodiments, the distance S1 is about ½ to about 100 times the gate length L8 (FIG. 19), the distance S2 is about ½ to about 100 times the gate length L8, the distance SIA is about ⅓ to about 300 times the gate length L8, and the distance S2A is about ⅓ to about 100 times the length L8.

The present disclosure in various embodiments provides a semiconductor device structure 100 including an active region 101 having at least two dummy gate electrode layers 168d disposed on each side of one or more active gate electrode layers 168a. The gate length of the dummy gate electrode layers 168d is different from the gate length of the active gate electrode layers 168a. Some embodiments may achieve advantages. For example, the active gate electrode layers 168a having a uniform gate length can lead to reduced mismatch in gate resistance, gate to environment total capacitance, and maximum power gain cut-off frequency.

An embodiment is a semiconductor device structure. The structure includes an active region, and the active region includes a fin extending over a substrate, a first dummy gate electrode layer disposed over the fin, a second dummy gate electrode layer adjacent the first dummy gate electrode layer, a third dummy gate electrode layer disposed over the fin and a fourth dummy gate electrode layer adjacent the third dummy gate electrode layer. The second and third dummy gate electrode layers are disposed between the first and fourth dummy gate electrode layers. The active region further includes an active gate electrode layer disposed over the fin, and the active gate electrode layer is disposed between the second and third dummy gate electrode layers.

Another embodiment is a semiconductor device structure. The structure includes a dielectric layer disposed over a substrate, and the dielectric layer includes a first portion having a first length and a second portion having a second length. The structure further includes an active region located between the first and second portions of the dielectric layer, and the active region includes a fin extending over the substrate, one or more active gate electrode layers disposed over the fin, and a first number of dummy gate electrode layers disposed on a first side of the one or more active gate electrode layers and adjacent the first portion of the dielectric layer. The first number and the first length have a first positive relationship. The active region further includes a second number of dummy gate electrode layers disposed on a second side of the one or more active gate electrode layers opposite the first side and adjacent the second portion of the dielectric layer.

A further embodiment is a method. The method includes depositing an interlayer dielectric (ILD) layer over a substrate and removing first, second, third, fourth, and fifth sacrificial gate stacks to form first, second, third, fourth, and fifth openings. The first opening is adjacent the second opening, and the fourth opening is adjacent the fifth opening. The method further includes shrinking the first, second, fourth, and fifth openings, the first opening has a greater shrinkage than the second opening, and the fifth opening has a greater shrinkage than the fourth opening. The method further includes depositing a first dummy gate electrode layer in the first opening, a second dummy gate electrode layer in the second opening, an active gate electrode layer in the third opening, a third dummy gate electrode layer in the fourth opening, and a fourth dummy gate electrode layer in the fifth opening. The first dummy gate electrode layer has a first gate length, the second dummy gate electrode layer has a second gate length, the active gate electrode layer has a third gate length, and the first and second gate lengths are different from the third gate length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
an active region, comprising:
a fin extending over a substrate;
a first dummy gate electrode layer disposed over the fin;
a second dummy gate electrode layer adjacent the first dummy gate electrode layer;
a third dummy gate electrode layer disposed over the fin;
a fourth dummy gate electrode layer adjacent the third dummy gate electrode layer, wherein the second and third dummy gate electrode layers are disposed between the first and fourth dummy gate electrode layers; and
an active gate electrode layer disposed over the fin, wherein the active gate electrode layer is disposed between the second and third dummy gate electrode layers.

2. The semiconductor device structure of claim 1, wherein the first dummy gate electrode layer comprises a first material, the second dummy gate electrode layer comprises a second material, the third dummy gate electrode layer comprises a third material, the fourth dummy gate electrode layer comprises a fourth material, and the active gate electrode layer comprises a fifth material.

3. The semiconductor device structure of claim 2, wherein the first, second, third, fourth, and fifth materials comprise a same material.

4. The semiconductor device structure of claim 2, wherein the first, second, third, and fourth materials are different from the fifth material.

5. The semiconductor device structure of claim 2, wherein the first material is different from the second material, and the second material is different from the fifth material.

6. The semiconductor device structure of claim 1, wherein the first dummy gate electrode layer has a first gate length, the second dummy gate electrode layer has a second gate length, and the active gate electrode layer has a third gate length.

7. The semiconductor device structure of claim 6, wherein the first gate length is greater than the second gate length, and the third gate length is greater than the second gate length and less than the first gate length.

8. A semiconductor device structure, comprising:
a dielectric layer disposed over a substrate, wherein the dielectric layer comprises a first portion having a first length and a second portion having a second length;
an active region located between the first and second portions of the dielectric layer, wherein the active region comprises:
a fin extending over the substrate;
one or more active gate electrode layers disposed over the fin;
a first number of dummy gate electrode layers disposed on a first side of the one or more active gate electrode layers and adjacent the first portion of the dielectric layer, wherein the first number and the first length have a first positive relationship; and
a second number of dummy gate electrode layers disposed on a second side of the one or more active gate electrode layers opposite the first side and adjacent the second portion of the dielectric layer.

9. The semiconductor device structure of claim 8, wherein the second number and the second length have a second positive relationship.

10. The semiconductor device structure of claim 8, wherein the first length is the same as the second length, and the first number is the same as the second number.

11. The semiconductor device structure of claim 8, wherein the first length is different from the second length, and the first number is different from the second number.

12. The semiconductor device structure of claim 11, wherein the first length is greater than the second length, and the first number is greater than the second number.

13. The semiconductor device structure of claim 8, wherein the first number is two, and the second number is two.

14. The semiconductor device structure of claim 8, wherein the first number is greater than two, and the second number is greater than two.

15. The semiconductor device structure of claim 14, wherein dummy gate electrode layers of the first number of dummy gate electrode layers comprise different materials.

16. A method, comprising:
depositing an interlayer dielectric (ILD) layer over a substrate;
removing first, second, third, fourth, and fifth sacrificial gate stacks to form first, second, third, fourth, and fifth openings, wherein the first opening is adjacent the second opening, and the fourth opening is adjacent the fifth opening;
shrinking the first, second, fourth, and fifth openings, wherein the first opening has a greater shrinkage than the second opening, and the fifth opening has a greater shrinkage than the fourth opening; and
depositing a first dummy gate electrode layer in the first opening, a second dummy gate electrode layer in the second opening, an active gate electrode layer in the third opening, a third dummy gate electrode layer in the fourth opening, and a fourth dummy gate electrode layer in the fifth opening, wherein the first dummy gate electrode layer has a first gate length, the second dummy gate electrode layer has a second gate length, the active gate electrode layer has a third gate length, and the first and second gate lengths are different from the third gate length.

17. The method of claim 16, wherein the first gate length is greater than the second gate length, and the third gate length is greater than the second gate length and smaller than the first gate length.

18. The method of claim 16, further comprising depositing a dielectric layer over the first, second, third, and fourth dummy gate electrode layers and the active gate electrode layer.

19. The method of claim 18, further comprising forming a conductive feature through the dielectric layer over the active gate electrode layer, wherein the first, second, third, and fourth dummy gate electrode layers are covered by the dielectric layer.

20. The method of claim 19, wherein the conductive feature is not formed over the first, second, third, and fourth dummy gate electrode layers.
